(19) United States
(12) Patent Application Publication
(10) Pub. No.: US 2009/0314536 A1
(43) Pub. Date: Dec. 24, 2009

(54) PRINTED CIRCUIT BOARD, ELECTRIC INSTRUMENT, AND SEMICONDUCTOR PACKAGE

(75) Inventors: Minoru TAKIZAWA, Sagamihara-Shi (JP); Hidenori TANAKA, Hachioji-Shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/490,159

(22) Filed: Jun. 23, 2009

(30) Foreign Application Priority Data
Jun. 24, 2008 (JP) 2008-164710

(51) Int. Cl. H05K 1/16; H01L 23/31

(52) U.S. Cl. 174/260; 257/690; 257/E23.123

(57) ABSTRACT

A printed circuit board, an electronic instrument, and a semiconductor package are provided that are excellent in bonding strength and easy in rework. The printed circuit board includes a printed wiring board, an electronic device that is the semiconductor package, and an adhesion part. A protection member of the electronic device is arranged along the periphery of a mounting surface of a package body so as to abut a mounting surface of the printed wiring board. The adhesion part is provided in a stepped part defined by a peripheral wall of the electronic device and part of the mounting surface of the printed wiring board in the vicinity of the electronic device.

### CROSS-REFERENCE TO RELATED APPLICATIONS

This application claims the benefit of priority of Japanese Patent Application No. 2008-164710, filed Jun. 24, 2008, the entire contents of which are incorporated herein by reference.

### BACKGROUND

1. Field

The present invention relates to a printed circuit board having surface-mount type semiconductor packages, in particular BGA (ball grid array) type semiconductor packages mounted thereon, an electronic instrument and a semiconductor package that have the printed circuit board accommodated therein, and a surface-mount type semiconductor package.

2. Description of the Related Art

In general, an electronic instrument includes a casing, a printed circuit board accommodated in the casing, and an electronic device mounted on the printed circuit board. The printed circuit board includes the electronic device and a printed wiring board having the electronic device mounted thereon.

Electronic circuits have included a surface-mount type semiconductor package called a BGA (ball grid array) type semiconductor package.

The BGA type semiconductor package includes a semiconductor device, a package body having semiconductors mounted and accommodated therein, and external connection electrodes formed on a mounting surface of the package body. The Printed wiring board is formed connection electrodes that electrically connected to the external connection electrodes of the BGA type semiconductor package. For ensuring a bonding strength, an adhesion part is formed in between the BGA type semiconductor package and the printed wiring board using an adhesive.

In the printed circuit board described in JP-A 2002-164472, a cover member is provided in the package body for covering a peripheral wall other than a mounting surface for the BGA type semiconductor package, so that the bonding strength of the adhesion part is improved by increasing the area coated with the adhesive.

In the printed circuit board in the Related Art, when it is difficult to secure an adhesion surface around the BGA type semiconductor package, the forming of the adhesion part having a sufficient adhesion area has been difficult.

On the other hand, if the adhesive part is formed on the mounting surface in the vicinity of external connection electrodes of the BGA type semiconductor package for ensuring the adhesion area, when incompatibility, such as a connection failure, is discovered between the external connection electrode of the BGA type semiconductor package and a connection electrode of a printed wiring board, it is difficult to dismount the BGA type semiconductor package from the printed wiring board, which is so-called rework.

### SUMMARY OF THE INVENTION

Accordingly, it is an object of the present invention to provide a printed circuit board, an electronic instrument, and a semiconductor package that are excellent in bonding strength and easy in rework as well.

In order to solve the problems described above, a printed circuit board and an electronic instrument according to the present invention include a printed wiring board having a first mounting surface and a plurality of connection electrodes formed on the first mounting surface at predetermined intervals; a plurality of external connection electrodes connected to the connection electrodes, respectively; a mold package having a semiconductor device mounted therein and electrically connected to the external connection electrodes and a second mounting surface having the external connection electrodes mounted thereon; a protection member arranged along the periphery of the second mounting surface so as to abut the first mounting surface; and an adhesion part provided on a stepped part defined by the peripheral wall of the mold package, the lateral surfaces of the protection member, and the first mounting surface.

Further, a semiconductor package according to the present invention includes an external connection electrode; a mold package having a semiconductor device mounted thereon and electrically connected to the external connection electrode and a mounting surface having the external connection electrode mounted thereon; and a protection member arranged along the periphery of the mounting surface of the mold package.

According to the present invention, a printed circuit board, an electronic instrument, and a semiconductor package that are excellent in bonding strength and easy in rework can be provided.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a portable computer as an electric instrument according to the present invention;

FIG. 2 is a sectional view of a printed circuit board according to the present invention;

FIG. 3 is a plan view of the printed circuit board according to the present invention;

FIG. 4 is a plan view of another example of the printed circuit board according to the present invention;

FIG. 5 is a plan view of another example of the printed circuit board according to the present invention;

FIG. 6 is a plan view of another example of the printed circuit board according to the present invention;

FIG. 7 is a plan view of another example of the printed circuit board according to the present invention;

FIG. 8 is a plan view of another example of the printed circuit board according to the present invention;

FIG. 9 is a sectional view of a circuit device as a semiconductor package according to the present invention; and

FIG. 10 is a flowchart of a manufacturing method of the printed circuit board according to the present invention.

### DETAILED DESCRIPTION

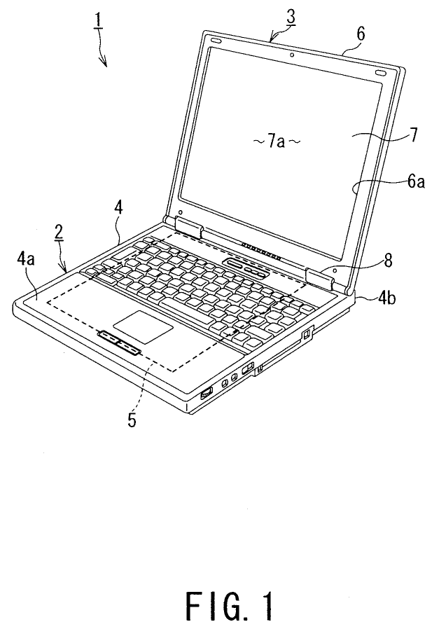

Embodiments of a printed circuit board, an electronic instrument, and a semiconductor package according to the present invention will be described with reference to FIGS. 1 to 10.

FIG. 1 is a perspective view of a portable computer that is an electronic instrument according to the present invention.

As shown in FIG. 1, a portable computer 1 as the electronic instrument includes a body 2 and a display unit 3.

The body 2 includes a box-shaped casing 4. The casing 4 includes an upper wall 4a, a side wall 4b, and a bottom wall (not shown). A printed circuit board 5 is accommodated within the casing 4. The printed circuit board 5 herein may be a mainboard (motherboard) of the portable computer 1 or a circuit board for fulfilling the function of a specific module.

The display unit 3 includes a display housing 6 and a liquid crystal display panel 7 housed within the display housing 6. The liquid crystal display panel 7 includes a display screen 7a. The display screen 7a is exposed outside the display housing 6 through an opening 6a in the front of the display housing 6.

The display unit 3 is supported at the rear end of the casing 4 via a hinge unit 8. The display unit 3 is rotatable due to the hinge unit 8 between a closed position where the display unit 3 falls down to cover the upper wall 4a of the casing 4 from the above and an opened position where the display unit 3 rises to expose the upper wall 4a and the display screen 7a.

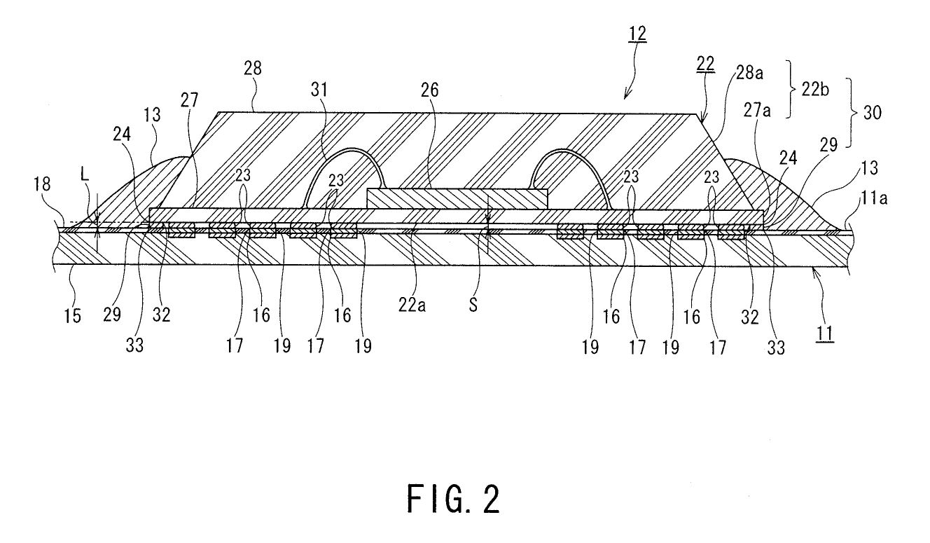

FIG. 2 is a sectional view of the printed circuit board according to the present invention.

As shown in FIG. 2, the printed circuit board 5 includes a printed wiring board 11, an electronic device 12 that is a semiconductor package, and an adhesion part 13. According to the embodiment, a BGA (ball grid array) type semiconductor package is exemplified as the electronic device 12. The electronic device 12 is not limited to the BGA, so that it may be an LGA (land grid array) and other semiconductor packages, for example. The electronic device 12 may widely incorporate any semiconductor package as long as it is a type of surface mount.

On a mounting surface 11a (a first mounting surface), which is one side of the printed wiring board 11, the electronic device 12 is mounted. The printed wiring board 11 includes an insulation substrate 15, a plurality of conductive patterns 16, connection electrodes 17, and a solder resist 18.

The insulation substrate 15 is formed by impregnating a reinforcing material, such as glass cloth, with an insulating resin, such as a phenol resin, an epoxy resin, a polyimide resin, and a BT resin.

The conductive pattern 16 formed on the surface of the insulation substrate 15 is made of a conductive material such as copper foil.

The connection electrodes 17 are arranged and exposed on the mounting surface 11a of the printed wiring board 11 at predetermined intervals. To the connection electrodes 17, the conductive patterns 16 are connected, respectively.

The solder resist 18 is provided on the outermost layer of the printed wiring board 11. The solder resist 18 is provided over substantially the entire surface of the printed wiring board 11 so as to cover the conductive patterns 16. The solder resist 18 is provided with openings 19 for exposing the connection electrodes 17 on the mounting surface 11a of the printed wiring board 11.

The electronic device 12 is a semiconductor package mounted on the printed wiring board 11. The electronic circuit of the printed circuit board 5 is composed of the electronic device 12 and the conductive patterns 16 of the printed wiring board 11.

The electronic device 12 includes a package body 22, which is a mold package, a plurality of external connection electrodes 23, and a protection member 24.

The package body 22 includes a semiconductor device 26, an interposer substrate 27, and a frame 28. On one side of the interposer substrate 27, the semiconductor device 26 is mounted while the frame 28 is provided. The semiconductor device 26 is housed in the frame 28. The other side of the interposer substrate 27 is arranged as a mounting surface 22a (second mounting surface) to oppose the printed wiring board 11. On the mounting surface 22a, the external connection electrodes 23 are provided. The semiconductor device 26 is electrically connected to the external connection electrodes 23 via wires 31. A peripheral wall 22b of the package body 22 is formed of a peripheral wall 27a of the interposer substrate 27 and a peripheral wall 28a of the frame 28.

The external connection electrodes 23 are arranged on the mounting surface 22a at predetermined intervals so as to be electrically connected to the connection electrodes 17 of the printed wiring board 11, respectively. The external connection electrodes 23 are arrayed on the mounting surface 22a in a lattice arrangement. The external connection electrode 23 is made of a solder ball, for example. When the electronic device 12 is reflow-heated in a state arranged on the mounting surface 11a, the external connection electrode 23 is bonded to the connection electrode 17 so as to mount the electronic device 12 on the printed wiring board 11.

The protection member 24 is arranged along the peripheral edge of the mounting surface 22a so as to abut the mounting surface 11a of the printed wiring board 11. Namely, the protection member 24 is a convex member arranged to protrude from the peripheral edge of the mounting surface 22a toward the mounting surface 11a of the printed wiring board 11. The protection member 24 is made of a metallic material, such as iron, stainless steel, aluminum, and copper, a heat-stable resin, and a glass epoxy substrate, for example. Preferably, the material of the protection member 24 may be appropriately selected for suppressing the heat deflection of the package body 22 generated when the electronic device 12 is reflow heated. A lateral surface 29, positioned at the peripheral edge of the mounting surface 22a among the faces of the protection member 24, constitutes a peripheral wall 30 of the electronic device 12 together with the peripheral wall 22b of the package body 22. An internal surface 32, opposing the lateral surface 29 among the faces of the protection member 24, is arranged to separate from the external connection electrodes 23. A protruding length L of the protection member 24 is determined to be smaller than the height of the external connection electrode 23 before being soldered. Specifically, the protruding length L of the protection member 24 is set substantially the same as or slightly smaller than A space S between the mounting surface 22a of the package body 22 and the mounting surface 11a of the printed wiring board 11. The space S is defined by the mass of the package body 22 and the number or the shape of the external connection electrodes 23 when the external connection electrodes 23 are soldered to the connection electrodes 17 of the printed wiring board 11 by a reflow system. The protection member 24 may also be formed integrally with the package body 22.

The adhesion part 13 fixes the electronic device 12 on the printed wiring board 11. The adhesion part 13 is provided in a stepped part 33 defined by the peripheral wall 30 of the electronic device 12 and part of the mounting surface 11a of the printed wiring board 11 in the vicinity of the electronic device 12. The adhesion part 13 may use a liquid adhesive, such as an epoxy, acrylic, urethane, and silicone adhesive, a thermosetting resin adhesive usable in a semi hardening state, such as a B-stage resin having melting characteristics at high temperature, a rubber denatured adhesive made of a thermosetting epoxy resin having silicone added thereto, and an adhesive of rubber, such as acrylic rubber, silicone rubber, acrylonitrile-butadiene rubber (NBR), and styrene-butadiene rubber (SBR), for example.

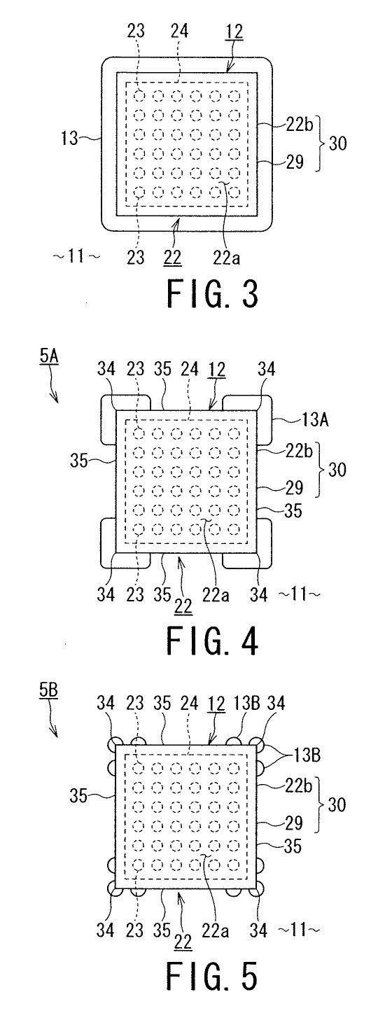

FIG. 3 is a plan view of a printed circuit board according to the present invention.

As shown in FIG. 3, the protection member 24 of the electronic device 12 is arranged along the entire peripheral edges of the mounting surface 22a of the package body 22. The adhesion part 13 is provided along the entire peripheries of the peripheral wall 22b of the package body 22 and the lateral surface 29 of the protection member 24. Namely, the adhesion part 13 is provided for covering the peripheral wall 30 of the electronic device 12 and part of the printed wiring board 11 in the vicinity of the peripheral wall 30.

The protection member 24 is a frame structure for shielding the external connection electrodes 23 from the external ambience. Since the adhesion part 13 covers the entire periphery of the mounting surface 22a of the package body 22, the possibility of the short-circuit between the near external connection electrodes 23 due to the admission or the deposition between the electronic device 12 and the printed wiring board 11 of a foreign material, such as dust, can be remarkably reduced.

FIGS. 4 to 8 are plan views, showing other examples of a printed circuit board according to the present invention.

As shown in FIG. 4, a printed circuit board 5A includes the electronic device 12 with a substantially rectangular shape in plan view and an adhesion part 13A.

The electronic device 12 is substantially rectangular-shaped, and its peripheral wall 30 includes corners 34 and sides 35. The protection member 24 is arranged along the entire periphery of the mounting surface 22a.

The adhesion parts 13A are provided at portions, which are biased toward the corner 34, of the sides 35 of the electronic device 12. That is, the adhesion parts 13A are provided for covering the corners 34 of the peripheral wall 30 in the electronic device 12 and parts of the printed wiring board 11 in its vicinity in an L-shape.

As shown in FIG. 5, a printed circuit board 5B includes the electronic device 12 with a substantially rectangular shape in plan view, the protection member 24, and an adhesion part 13B.

The adhesion parts 13B are provided in corner portions of the electronic device 12, respectively. That is, the adhesion parts 13B are respectively provided for covering the corners 34 of the peripheral wall 30 in the electronic device 12 and parts of the printed wiring board 11 in the vicinity of the corners 34 in a circular shape.

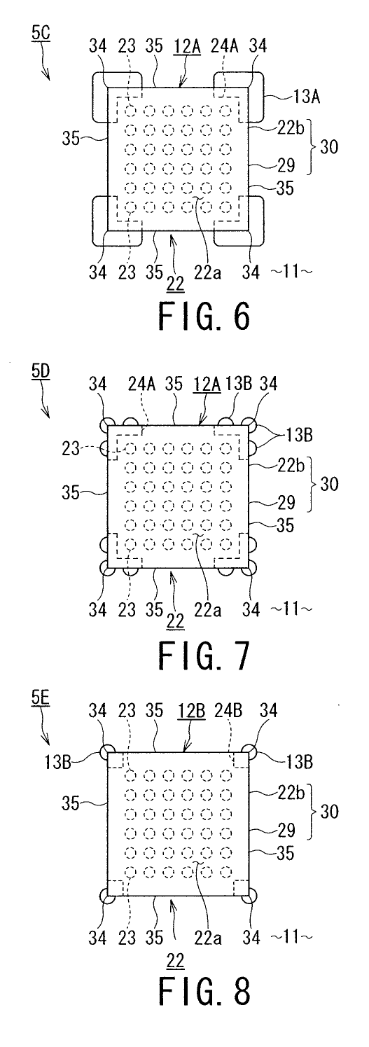

As shown in FIG. 6, a printed circuit board 5C includes an electronic device 12A with a substantially rectangular shape in plan view and the adhesion part 13A.

The electronic device 12A is substantially rectangular-shaped, and its peripheral wall 30 includes the corners 34 and the sides 35. Protection members 24A are arranged along the periphery of the mounting surface 22a at portions, which are biased toward the corner 34, of the sides 35 of the electronic device 12A. That is, the protection members 24A are provided in corner portions of the mounting surface 22a in an L-shape, respectively.

The adhesion parts 13A are provided at positions corresponding to the protection members 24, respectively. The adhesion parts 13A are provided in portions, which are biased toward the corner 34, of the sides 35 of the electronic device 12A. Namely, the adhesion parts 13A are provided for covering the corners 34 of the peripheral wall 30 in the electronic device 12A and parts of the printed wiring board 11 in the vicinity of the peripheral wall 30 in an L shape.

As shown in FIG. 7, a printed circuit board 5D includes the electronic device 12A with a substantially rectangular shape in plan view and the adhesion part 13B.

The adhesion parts 13B are provided at the corners 34 of the electronic device 12A, respectively. That is, the adhesion parts 13B are respectively provided for covering the corners 34 of the peripheral wall 30 in the electronic device 12A and parts of the printed wiring board 11 in the vicinity of the corners 34 in a circular shape.

As shown in FIG. 8, a printed circuit board 5E includes an electronic device 12B with a substantially rectangular shape in plan view and the adhesion part 13B.

The electronic device 12B is substantially rectangular-shaped, and its peripheral wall 30 includes the corners 34 and the sides 35. Protection parts 24B are provided along the periphery of the mounting surface 22a at positions corresponding to the corners 34 of the electronic device 12B, respectively.

The adhesion parts 13B are provided at positions corresponding to the protection members 24B, respectively. The adhesion part 13B is provided at every corner 34 of the electronic device 12B. That is, the adhesion parts 13B are respectively provided for covering the corners 34 of the peripheral wall 30 in the electronic device 12B and parts of the printed wiring board 11 in the vicinity of the corners 34 in a circular shape.

Then, a method for mounting the electronic device 12 on the printed wiring board 11 will be described. Since the electronic instruments 12A, 12B, 12C, 12D, and 12E can be mounted on the electronic device 12 in the same way, its description is omitted.

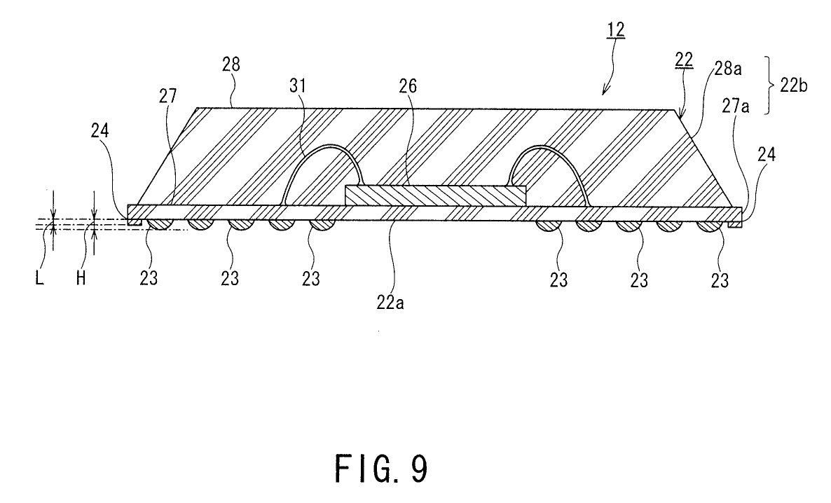

FIG. 9 is a sectional view of a circuit device serving as a semiconductor package according to the present invention.

As shown in FIG. 9, the electronic device 12 before it is mounted on the printed wiring board 11 includes the external connection electrodes 23 that protrude further than the protruding length L of the protection member 24. The difference between the height H of the external connection electrode 23 before it is soldered and the protruding length L of the protection member 24 is provided such that when the electronic device 12 and the printed wiring board 11 are reflow heated, the external connection electrode 23 does not inhibit the access of the package body 22 to the printed wiring board 11 due to melting.

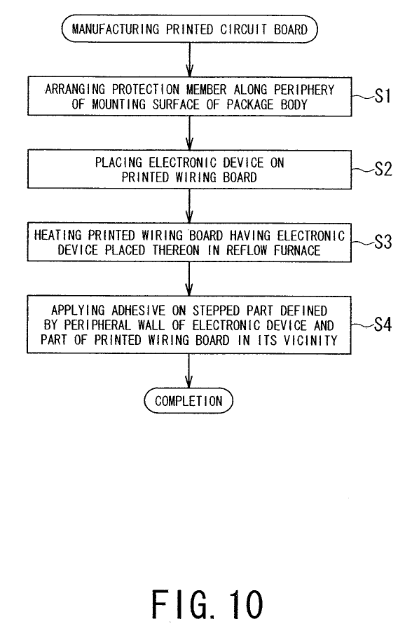

FIG. 10 is a flowchart of a manufacturing method of the printed circuit board according to the present invention.

As shown in FIG. 10, first, at Step S1, a manufacturer of the printed circuit board 5 forms the electronic device 12 by providing the protection member 24 along the periphery of the mounting surface 22a in the package body 22.

Then, at Step S2, the manufacturer of the printed circuit board 5 places the electronic device 12 on the printed wiring board 11.

Next, at Step S3, the manufacturer of the printed circuit board 5 heats the printed wiring board 11 having the electronic device 12 placed thereon by putting it in a reflow furnace. Thereby, as shown in FIG. 2, the external connection electrodes 23 are bonded to the connection electrodes 17, respectively.

Then, at Step S4, the manufacturer of the printed circuit board 5 applies an adhesive to the stepped part 33, defined by the peripheral wall 30 of the electronic device 12 and part of the mounting surface 11a of the printed wiring board 11 in the vicinity of the peripheral wall 30, so as to complete the operation. At this time, the adhesive is applied over the entire periphery of the electronic device 12. When the adhesive is cured, the electronic device 12 is bonded and fixed to the printed wiring board 11.

Thereby, the printed circuit board 5 has been manufactured.

During reworking, the electronic device 12 can be easily dismounted from the printed circuit board 5 by removing the adhesion part 13 and increasing the solder temperature to its melting point.

In the printed circuit boards 5, 5A, 5B, 5C, 5D, and 5E according to the embodiments, the electronic instruments 12, 12A, and 12B are respectively provided with the peripheral wall 22b of the package body 22, the lateral surfaces 29, 29A, and 29B of the protection members 24, 24A, and 24B, and the stepped part 33 roomed in the printed wiring board 11 for forming adhesion surfaces of the adhesion parts 13, 13A, and 13B. Hence, in the electronic instruments 12, 12A, and 12B, the rigidity of the package body 22 can be maintained larger due to the protection members 24, 24A, and 24B, while the area of the adhesion surface can be increased. Accordingly, the mechanical bonding strength between the electronic instruments 12, 12A, and 12B and the printed wiring board 11 due to the adhesion parts 13, 13A, and 13B is increased for improving durability against a stress, achieving reliable high-accuracy mounting.

Even when the shape of the peripheral wall 28a of the frame 28 of the respective electronic instruments 12, 12A, and 12B is not suitable for providing the respective adhesion parts 13, 13A, and 13B, i.e., even when a sufficient region for forming any one of the adhesion parts 13, 13A, and 13B cannot be secured in the peripheral wall 22b of the package body 22, in addition to the peripheral wall 27a of the interposer substrate 27, the area of the respective lateral surfaces 29, 29A, and 29B of the protection members 24, 24A, and 24B can be added to the area of the adhesion surface. Hence, even when the sufficient adhesion surface cannot be secured on the package body 22, the mechanical bonding strength between the electronic instruments 12, 12A, and 12B and the printed wiring board 11 is increased due to the adhesion parts 13, 13A, and 13B for improving durability against a stress, achieving reliable high-accuracy mounting.

Furthermore, the adhesion parts 13, 13A, and 13B cannot drift into the mounting surface 22a of the package body 22, which is the periphery of the external connection electrodes 23, owing to the protection members 24, 24A, and 24B, so that when dismounting the electronic instruments 12, 12A, and 12B from the printed wiring board 11, the adhesion parts 13, 13A, and 13B can be easily removed. Hence, while the mechanical strength of the adhesion parts 13, 13A, and 13B between the electronic device 12 and the printed wiring board 11 is improved, the rework can be easily made.

Accordingly, the printed circuit board 5, 5A, 5B, 5C, 5D, and 5E, the portable computer 1, and the electronic device 12, 12A, and 12B according to the embodiments are excellent in bonding strength and are easy in reworking as well.

What is claimed is:

1. A printed circuit board comprising:
a printed wiring board comprising a first mounting surface and a plurality of connection electrodes on the first mounting surface at predetermined intervals;
a plurality of external connection electrodes connected to the connection electrodes;
a mold package comprising a semiconductor device configured to electrically connect to the plurality of external connection electrodes, and a second mounting surface underneath the plurality of external connection electrodes;
a protector along a periphery of the second mounting surface in order to touch the first mounting surface; and
an adhesive portion on a stepped portion defined by a peripheral wall of the mold package, the lateral surfaces of the protector, and the first mounting surface.

2. The board of claim 1,
wherein the protector is located along an entire periphery of the second mounting surface, and
the adhesive portion is located along entire peripheries of the peripheral wall of the mold package and the lateral surface of the protector.

3. The board of claim 1,
wherein the protector is located along an entire periphery of the second mounting surface, and
the adhesive portions are located toward corners on sides of the peripheral wall of the mold package and the lateral surfaces of the protector.

4. The board of claim 1,
wherein the protector is located along an entire periphery of the second mounting surface, and
the adhesive portions are located in corner portions of the peripheral wall of the mold package and the lateral surface of the protector.

5. The board of claim 1,
wherein the protectors are located toward corners on sides of the mold package, and
the adhesive portions are located toward corners on sides of the peripheral wall of the mold package and the lateral surface of the protector.

6. The board of claim 1,
wherein the protectors are located toward corners on the sides of the mold package, and
the adhesive portions are located in corner portions of the peripheral wall of the mold package and the lateral surface of the protector.

7. The board of claim 1,
wherein the protectors are located in corner portions of the mold package, and
the adhesive portions are located in corner portions of the peripheral wall of the mold package and the lateral surface of the protector.

8. An electronic instrument comprising a casing comprising a printed circuit board,
wherein the printed circuit board comprises:
a printed wiring board comprising a first mounting surface and a plurality of connection electrodes on the first mounting surface at predetermined intervals;
a plurality of external connection electrodes connected to the connection electrodes;
a mold package comprising a semiconductor device and electrically connected to the external connection electrodes and a second mounting surface underneath the external connection electrodes;
a protector located along a periphery of the second mounting surface in order to touch the first mounting surface; and
an adhesive portion on a stepped portion defined by a peripheral wall of the mold package, the lateral surfaces of the protector, and the first mounting surface.

9. A semiconductor package comprising:
an external connection electrode;
a mold package comprising a semiconductor device electrically connected to the external connection electrode and a mounting surface underneath the external connection electrode; and
a protector located along a periphery of the mounting surface of the mold package.
